(19) United States
(12) Patent Application Publication
(10) Pub. No.: US 2026/0088852 A1
(43) Pub. Date: Mar. 26, 2026

(54) DUAL RESONANCE HELPER FOR RADIO-FREQUENCY FILTER

(71) Applicant: SKYWORKS SOLUTIONS, INC., Irvine, CA (US)

(72) Inventors: Manjunath MACHNOOR, Cedar Rapids, IA (US); Tao WU, Marion, IA (US)

(21) Appl. No.: 19/334,837

(22) Filed: Sep. 20, 2025

Related U.S. Application Data
(60) Provisional application No. 63/696,993, filed on Sep. 20, 2024.

(51) Int. Cl. H04B 1/40; H03H 9/02; H03H 9/64

(52) U.S. Cl. CPC H04B 1/40; H03H 9/02007; H03H 9/64

(57) ABSTRACT

A radio-frequency filter circuit can include a first node and a second node, a series path implemented between the first and second nodes and including a series resonator, and a shunt path that couples a shunt node along the series path to a ground and including a shunt resonator. The filter circuit can further include a helper circuit implemented along the shunt path and configured to provide control of a plurality of harmonics associated with a resonance frequency provided by the series and shunt resonators.

### CROSS-REFERENCE TO RELATED APPLICATION(S)

This application claims priority to U.S. Provisional Application No. 63/696,993 filed Sep. 20, 2024, entitled DUAL RESONANCE HELPER FOR RADIO-FREQUENCY FILTER, the disclosure of which is hereby expressly incorporated by reference herein in its entirety.

### BACKGROUND

### Field

The present disclosure relates to radio-frequency filter circuits, devices and methods.

### Description of the Related Art

A radio-frequency (RF) filter is typically designed to pass or exclude a signal having a frequency in a frequency range which is also commonly referred to as a frequency band. For example, a band-pass filter is designed to pass signals having frequencies within a respective frequency band, and reject signals having frequencies outside the frequency band.

### SUMMARY

In accordance with a number of implementations, the present disclosure relates to a radio-frequency filter circuit that includes a first node and a second node, a series path implemented between the first and second nodes, with the series path including a series resonator, and a shunt path that couples a shunt node along the series path to a ground, with the shunt path including a shunt resonator. The radio-frequency filter circuit further includes a helper circuit implemented along the shunt path and configured to provide control of a plurality of harmonics associated with a resonance frequency provided by the series and shunt resonators.

In some embodiments, the radio-frequency filter circuit can be configured to provide a band-pass functionality for a frequency band about the resonance frequency. In some embodiments, the plurality of harmonics can include a second harmonic and a third harmonic.

In some embodiments, the helper circuit can be implemented between the shunt resonator and the ground. The helper circuit can include a series arrangement of a first inductance Lₛₑᵣ and a parallel combination, such that one end of Lₛₑᵣ is coupled to the shunt resonator and the other end of Lₛₑᵣ is coupled to the parallel combination, with the parallel combination including a first path having a second inductance Lₛ in series with a capacitance Cₛ and a second path having a third inductance L_{BW}. Lₛₑᵣ, Lₛ, Cₛ and L_{BW} can have values that satisfy a condition

$${ω}^{2} {L}_{s} < \frac{1}{{C}_{s}} < {ω}^{2} ( {L}_{s} + {L}_{BW} ) where ω = 2 π f$$

with f being the resonance frequency. Lₛₑᵣ, Lₛ, Cₛ and L_{BW} can have values selected to provide a slightly negative value for an equivalent inductance for the helper circuit.

In some embodiments, Lₛ and L_{BW} can have values selected to have comparable values that are within 50%, 40%, 30%, 20% or 15% of each other. Lₛₑᵣ can have a value selected to be greater than each of Lₛ and L_{BW}.

In some embodiments, the radio-frequency filter circuit can further include one or more additional sets of a series resonator and a shunt resonator, such that each additional series resonator is implemented along the series path and the respective additional shunt resonator is part of a shunt path that couples a shunt node corresponding to the additional series resonator to the ground. The helper circuit can be implemented such that its corresponding shunt node is coupled to one of the first and second nodes or a node between two series resonators. The first node can be an input node and the second node can be an output node, and the helper circuit can be implemented such that its corresponding shunt node is coupled to the input node.

In some implementations, the present disclosure relates to a radio-frequency module that includes a packaging substrate and a filter circuit implemented with respect to the packaging substrate. The filter circuit includes a first node and a second node, a series path implemented between the first and second nodes such that the series path includes a series resonator, and a shunt path that couples a shunt node along the series path to a ground such that the shunt path includes a shunt resonator. The filter circuit further includes a helper circuit implemented along the shunt path and configured to provide control of a plurality of harmonics associated with a resonance frequency provided by the series and shunt resonators.

In some embodiments, the helper circuit can include a series arrangement of a first inductance Lₛₑᵣ and a parallel combination, such that one end of Lₛₑᵣ is coupled to the shunt resonator and the other end of Lₛₑᵣ is coupled to the parallel combination, with the parallel combination including a first path having a second inductance Lₛ in series with a capacitance Cₛ and a second path having a third inductance L_{BW}. In some embodiments, the packaging substrate can include multiple layers, and each of some or all of Lₛₑᵣ, Lₛ, Cₛ and L_{BW} can be implemented as a part of one or more of the multiple layers.

In some embodiments, the radio-frequency module can further include one or more chips mounted on the packaging substrate. At least some of the one or more chips can include the series resonator and the shunt resonator.

In some embodiments, each of the series and shunt resonators can be implemented as an acoustic wave resonator.

In some implementations, the present disclosure relates to a wireless device that includes an antenna and a radio-frequency circuit in communication with the antenna and configured to support either or both of transmit and receive operations of the wireless device. The radio-frequency circuit has a filter circuit that includes a first node and a second node, a series path implemented between the first and second nodes such that the series path includes a series resonator, and a shunt path that couples a shunt node along the series path to a ground such that the shunt path includes a shunt resonator. The filter circuit further includes a helper circuit implemented along the shunt path and configured to provide control of a plurality of harmonics associated with a resonance frequency provided by the series and shunt resonators.

In some embodiments, the radio-frequency filter circuit can be configured to provide a band-pass functionality for a frequency band about the resonance frequency. The frequency band can include, for example, a B41 band having a frequency range of 2.496 GHz to 2.690 GHz.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A shows an example of a filter circuit implemented to include two stages between an input and an output.

FIG. 1B shows a frequency response provided by the filter circuit of FIG. 1A configured to provide band-pass functionality.

FIG. 2 shows an example of a filter circuit implemented to include two stages between an input and an output, and including a dual resonance helper.

FIG. 3A shows a filter circuit that is a more specific example of the filter circuit of FIG. 2.

FIG. 3B shows a frequency response provided by the filter circuit of FIG. 3A configured to provide band-pass functionality.

FIG. 4 shows comparisons of various frequency response plots for the filter circuit of FIG. 1A and the filter circuit of FIG. 3A.

FIG. 5A shows an example of a dual resonance helper that can be implemented in the filter circuit of FIG. 3A.

FIG. 5B shows an impedance plot for the dual resonance helper of FIG. 5A.

FIG. 6 shows that in some embodiments, a packaged module having a packaging substrate can include a filter circuit as described herein.

FIG. 7 depicts a packaged module that can be a more specific example of the packaged module of FIG. 6.

FIG. 8 shows that in some embodiments, some or all of the passive elements in FIG. 7 can be implemented as parts of the substrate.

FIG. 9 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

A radio-frequency (RF) filter is typically designed to pass or exclude a signal having a frequency in a frequency range which is also commonly referred to as a frequency band. For example, a band-pass filter is designed to pass signals having frequencies within a respective frequency band, and reject signals having frequencies outside the frequency band.

A response of a filter, such as the foregoing band-pass filter, to a signal within its frequency band is referred to as in-band response, and out-of-band (OOB) response refers to the filter's response to a signal outside of the frequency band. Typically, filter designs are constrained by a trade-off between in-band and OOB performance. For example, use of multiple filter stages can achieve better OOB performance (e.g., better OOB rejection), but at the cost of in-band loss. Also, additional filter stages can increase the required area on a device where the filter is implemented.

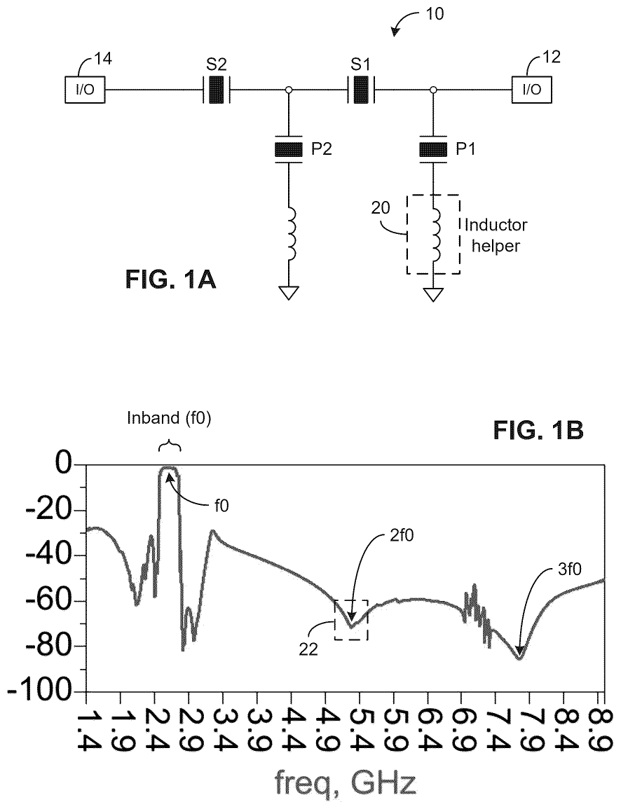

FIG. 1A shows an example of a filter circuit 10 implemented to include two stages between an input (e.g., I/O node 12) and an output (e.g., I/O node 14). The first stage is shown to include a first series resonator S1 and a first shunt resonator P1 that couples the input node 12 to ground through an inductor helper 20. The second stage is shown to include a second series resonator S2 between S1 and the output node 14, and a second shunt resonator P2 that couples a node between S1 and S2 to the ground.

FIG. 1B shows a frequency response provided by the filter circuit 10 of FIG. 1A configured to provide band-pass functionality for an example B41 Tx frequency band with a frequency range of 2.496 GHz to 2.690 GHz. With such a frequency range for the fundamental resonance frequency f0, frequency ranges for the second (2f0) and third (3f0) harmonic frequencies can be 4.992 GHz to 5.380 GHz and 7.448 GHz to 8.048 GHz, respectively. Accordingly, an in-band range corresponding to the fundamental resonance frequency f0 is indicated, and second (2f0) and third (3f0) harmonic frequency responses are shown outside of the in-band range.

It will be understood that while various examples are described herein in the context of the example B41 Tx frequency band, one or more features of the present disclosure can also be implemented for other frequency bands, including Tx bands and/or non-Tx bands.

Referring to FIGS. 1A and 1B, the inductor helper 20 between the first shunt resonator P1 and the ground is shown to have an inductance configured to provide a single helper functionality. More particularly, the inductor helper 20 can affect only the notch 22 associated with the second harmonic 2f0, and not provide any significant effect for other notch(es). Accordingly, the inductor helper does not provide sufficient tuning functionality to control a plurality of harmonics such as 2f0, 3f0 rejections.

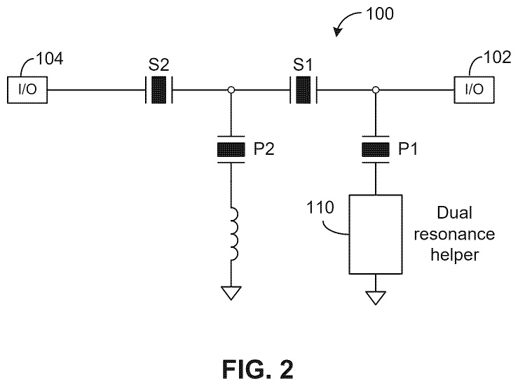

FIG. 2 shows an example of a filter circuit 100 implemented to include two stages between an input (e.g., I/O node 102) and an output (e.g., I/O node 104). The first stage is shown to include a first series resonator S1 and a first shunt resonator P1 that couples the input node 102 to ground through a dual resonance helper 110. The second stage is shown to include a second series resonator S2 between S1 and the output node 104, and a second shunt resonator P2 that couples a node between S1 and S2 to the ground through an inductance. It will be understood that in some embodiments, such an inductance between P2 and the ground may also be replaced with a dual resonance helper similar to the helper circuit 110 associated with P1.

In some embodiments, the dual resonance helper 110 in FIG. 2 can be implemented to provide significant effects for a plurality of notches or frequency spectrum features associated with respective harmonics. In some embodiments, such a dual resonance helper can be implemented to provide such control of notches to help meet OOB design specifications with a smaller number of filtering stages and a smaller filter size.

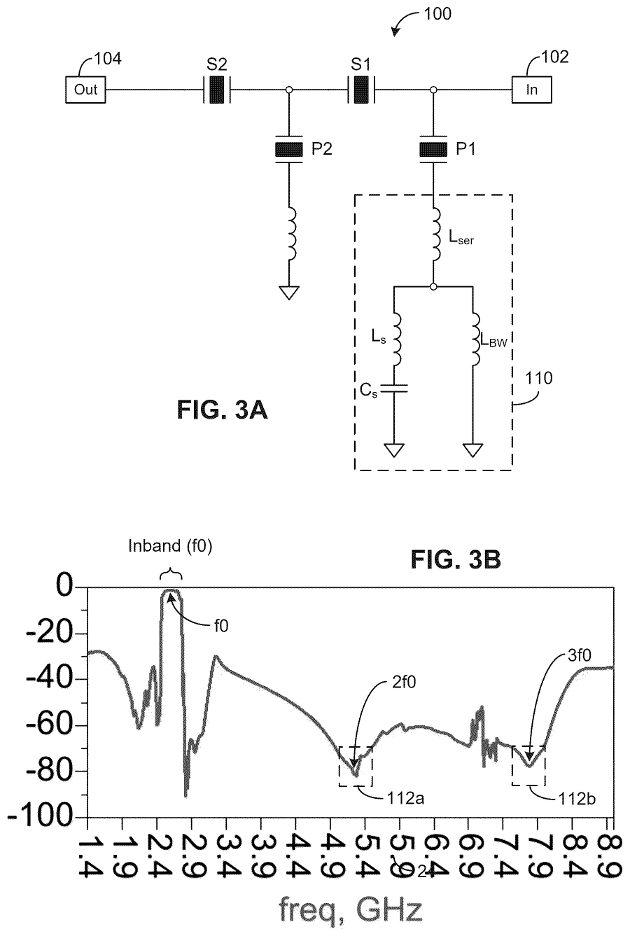

FIG. 3A shows a filter circuit 100 that is a more specific example of the filter circuit 100 of FIG. 2. FIG. 3B shows a frequency response provided by the filter circuit 100 of FIG. 3A configured to provide band-pass functionality for the example B41 Tx frequency band discussed above in reference to FIG. 1B. Accordingly, an in-band range corresponding to a fundamental resonance frequency f0 is indicated, and second (2f0) and third (3f0) harmonic frequency responses are shown outside of the in-band range.

FIG. 3A shows that in some embodiments, the dual resonance helper 110 can include an inductance Lₛₑᵣ and a parallel combination in series between the resonator P1 and the ground. Such a parallel combination can include a branch having a series arrangement of inductance Lₛ and capacitance Cₛ electrically parallel with another branch having an inductance L_{BW}, between the resonator P1 and the ground. Configured in the foregoing manner, and as shown in FIG. 3B, the dual resonance helper 110 can provide significant effects for both of the notch 112a associated with the second harmonic 2f0 and the notch 112b associated with the third harmonic 3f0. Accordingly, the dual resonance helper 110 can provide tuning functionality to control a plurality of harmonics such as 2f0, 3f0 rejections.

It will be understood that while various examples are described herein in the context of control of dual OOB notches associated with second and third harmonics 2f0, 3f0, one or more features of the present disclosure can also be implemented for other numbers of OOB notches of other frequency spectrum features, including configurations involving more than two OOB notches.

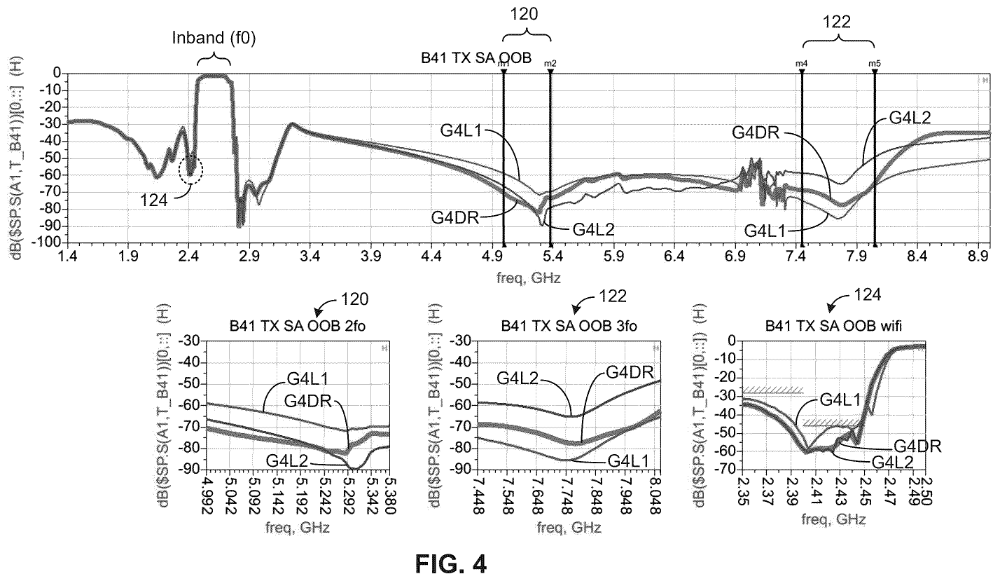

FIG. 4 shows comparisons of various frequency response plots for the filter circuit 10 of FIG. 1A and the filter circuit 100 of FIG. 3A. More particularly, the upper panel shows frequency responses similar to the frequency responses of FIGS. 1B and 3B; the lower left panel shows an enlarged portion 120 corresponding to the example B41 Tx OOB second harmonic (2f0) frequency range 120; the lower middle panel shows an enlarged portion 122 corresponding to the example B41 Tx OOB third harmonic (3f0) frequency range 122; and the lower right panel shows an enlarged portion 124 corresponding to the lower edge portion 124 of the example B41 Tx fundamental frequency (f0) band.

Referring to FIG. 4, G4L1 refers to a configuration of the inductor helper 20 of FIG. 1A where the value of inductance is approximately 0.0 nH; G4L2 refers to a configuration of the inductor helper 20 of FIG. 1A where the value of inductance is approximately 1.6 nH; and G4Dr refers to a configuration of the dual resonance helper 110 of FIG. 3A where the values of Lₛₑᵣ, L_{BW}, Cₛ and Lₛ are approximately as indicated in Table 1.

TABLE 1

| Parameter | Value | |
|---|---|---|
| Lₛₑᵣ | 1.2 | nH |
| L_{BW} | 0.4 | nH |
| Lₛ | 0.35 | nH |
| Cₛ | 0.65 | pF |

Configured in the foregoing manner, and referring to FIG. 4 and Table 1, it is noted that for the G4L1 configuration (approximately 0.0 nH for the inductor helper 20 of FIG. 1A), the third harmonic (3f0) rejection is improved at the expense of the second harmonic (2f0) rejection becoming worse. For the G4L2 configuration (approximately 1.6 nH for the inductor helper 20 of FIG. 1A), the second harmonic (2f0) rejection is improved at the expense of the third harmonic (3f0) rejection becoming worse. For the G4DR configuration of FIG. 3A and Table 1, both of the second harmonic (2f0) rejection and the third harmonic (3f0) rejection are shown to be improved without compromising the in-band performance.

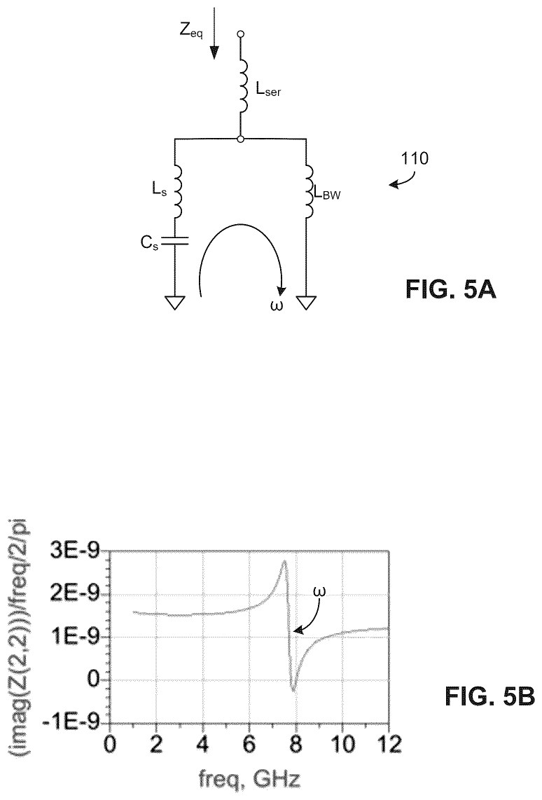

FIG. 5A shows the dual resonance helper 110 of FIG. 3A by itself, and FIG. 5B shows an impedance plot for the dual resonance helper 110. Such a circuit can include an equivalent impedance Z_{eq} as seen from the shunt resonator (P1 in FIG. 3B) and a characteristic frequency ω.

Referring to FIGS. 5A and 5B, selection of the example parameters of Table 1 can be achieved as follows. It is noted that the equivalent impedance Z_{eq} can be expressed as

$${Z}_{eq} = j ω {L}_{ser} + ( j ω {L}_{BW} ) ‖ ( j ω {L}_{s} + \frac{1}{j ω {C}_{s}} ) . \qquad ( 1 )$$

The second term of Equation 1 for the parallel combination can be re-written as

$$( j ω {L}_{BW} ) ‖ ( j ω {L}_{s} + \frac{1}{j ω {C}_{s}} ) = ( \frac{j ω {L}_{BW} * ( j ω {L}_{s} + \frac{1}{j ω {C}_{s}} )}{j ω {L}_{BW} + j ω {L}_{s} + \frac{1}{j ω {C}_{s}}} ) \qquad ( 2 A )$$

which can be re-written as

$$( j ω {L}_{BW} ) ‖ ( j ω {L}_{s} + \frac{1}{j ω {C}_{s}} ) = j ω {L}_{BW} ( \frac{1 - {ω}^{2} {L}_{s} {C}_{s}}{1 - {ω}^{2} {L}_{BW} {C}_{s} - {ω}^{2} {L}_{s} {C}_{s}} ) . \qquad ( 2 B )$$

With such a parallel-combination term expressed in Equation 2B, Equation 1 can be expressed as

$${Z}_{eq} = j ω {L}_{ser} + j ω {L}_{BW} ( \frac{\frac{1}{{C}_{s}} - {ω}^{2} {L}_{s}}{\frac{1}{{C}_{s}} - {ω}^{2} ( {L}_{s} + {L}_{BW} )} ) , \qquad ( 3 A )$$

$$or$$

$${Z}_{eq} = j ω {L}_{eq} \qquad ( 3 B )$$

where L_{eq} is representative of an equivalent inductance of the parallel combination and expressed as

$${L}_{eq} = {L}_{ser} + {L}_{BW} ( \frac{\frac{1}{{C}_{s}} - {ω}^{2} {L}_{s}}{\frac{1}{{C}_{s}} - {ω}^{2} ( {L}_{s} + {L}_{BW} )} ) . \qquad ( 3 C )$$

In Equations 3A and 3C, the term

$$T = ( \frac{\frac{1}{{C}_{s}} - {ω}^{2} {L}_{s}}{\frac{1}{{C}_{s}} - {ω}^{2} ( {L}_{s} + {L}_{BW} )} )$$

provides a relatively sudden change in the equivalent impedance Z_{eq} and equivalent inductance L_{eq}, respectively, as the frequency ω approaches a resonance condition where ω=ω_{c}, with ω_{c} being a corresponding resonance frequency. At the resonance condition, the denominator of the term T is at or close to zero, thereby resulting in the value of T being very large. It is noted that as the frequency ω approaches ω_{c} from the left side in a frequency spectrum (i.e., from the lower frequency side), the denominator of T has a positive value and thus results in a very large positive values of Z_{eq} and L_{eq}. Such an effect for the equivalent impedance Z_{eq} is shown in FIG. 5B. As the frequency ω approaches ω_{c} from the right side in a frequency spectrum (i.e., from the higher frequency side), the denominator of T has a negative value and thus results in a very large negative values of Z_{eq} and L_{eq}; and such an effect for the equivalent impedance Z_{eq} is also shown in FIG. 5B.

In the foregoing positive and negative values of the term T, suppose that a negative T value is desired. Such a negative T value can be achieved with a condition

$${ω}^{2} {L}_{s} < \frac{1}{{C}_{s}} < {ω}^{2} ( {L}_{s} + {L}_{BW} ) . \qquad ( 4 )$$

With the foregoing negative T value subject to the example condition of Equation 4, the equivalent inductance L_{eq} of Equation 3C, and thus the equivalent impedance Z_{eq} of Equation 3B, can become negative based on the choice of the components including the inductances Lₛ and L_{BW}.

In some embodiments, the components Lₛₑᵣ, Lₛ, Cₛ and L_{BW} of the dual resonance helper 110 of FIGS. 3A and 5A can be selected to satisfy the condition of Equation 4 and provide a slightly negative value for the equivalent inductance L_{eq} of Equation 3C, and thus the equivalent impedance Z_{eq} of Equation 3B. In some embodiments, the values of Lₛ and L_{BW} can also be selected to be comparable, as in the examples of Table 1, such that values of Lₛ and L_{BW} are within, for example, 50%, 40%, 30%, 20% or 15% of each other.

For the example B41 Tx band described herein, and referring to the example of Table 1, the parameters listed therein can be selected as follows. Larger inductance and capacitance among the components can be selected for easy or practical implementations (e.g., on and/or within a packaging substrate). For example, suppose that Lₛₑᵣ less than 2 nH and Cₛ less than 1 pF are desired to allow such easy implementations. The example values of Lₛₑᵣ=1.2 nH and Cₛ=0.65 pF allow such implementations.

Further, L_{BW} can be selected to provide control of bandwidth associated with the negative equivalent inductance L_{eq} of Equation 3C. It was found that L_{BW} of 0.4 nH was sufficient enough to cover the third harmonic (3f0) bandwidth. With such a selection of L_{BW}, Lₛ can be selected to be comparable to L_{BW} (e.g., Lₛ=0.35 nH) as mentioned above.

It will be understood that parameters Lₛₑᵣ, Lₛ, Cₛ and L_{BW} can also be selected in similar manners for other frequency bands.

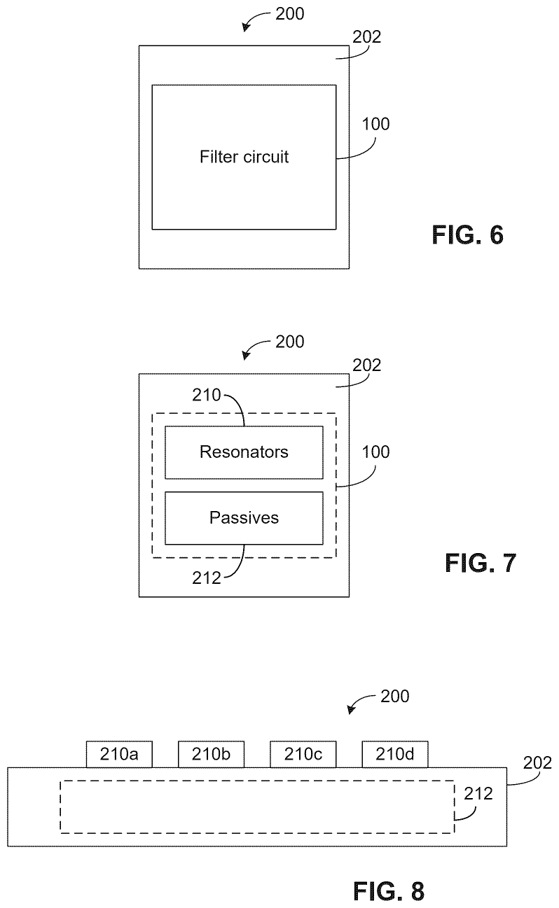

In some embodiments, one or more features of the present disclosure can be implemented in various products. For example, FIG. 6 shows that in some embodiments, a packaged module 200 having a packaging substrate 202 can include a filter circuit 100 as described herein. In some embodiments, at least some of the filter circuit 100 can be implemented on and/or within the packaging substrate 202.

FIG. 7 depicts a packaged module 200 that can be a more specific example of the packaged module 200 of FIG. 6. In the example of FIG. 7, a filter circuit 100 is shown to include a plurality of resonators 210 and a plurality of passive elements 212. In the example context of the filter circuit 100 of FIG. 3A, the resonators 210 in FIG. 7 can include the resonators S1, P1, S2 and P2; and the passive elements 212 in FIG. 7 can include the inductance elements Lₛₑᵣ, Lₛ and L_{BW} and the capacitance element Cₛ.

In some embodiments, the resonators 210 in FIG. 7 can be implemented as resonator devices such as acoustic wave devices (e.g., surface acoustic wave (SAW) devices, bulk acoustic wave (BAW) devices, etc.), non-acoustic wave devices, or some combination thereof.

FIG. 8 shows that in some embodiments, some or all of the passive elements 212 in FIG. 7 can be implemented as parts of the substrate 202. For example, in FIG. 8, a plurality of resonators 210a, 210b, 210c, 210d are shown to be implemented on a packaging substrate 202 having a plurality of layers. Some or all of such layers of the packaging substrate 202 can include passive elements 212 that form a filter circuit (100 in FIG. 7) along with the resonators 210a, 210b, 210c, 210d.

In some embodiments, each of the inductance elements in FIG. 8 can be implemented on one layer or on a plurality of layers. In the latter case where an inductance is implemented on a plurality of layers, conductive feature(s) such as conductive via(s) can be utilized to provide appropriate electrical connection(s) to provide a desired inductance.

In some embodiments, the packaging substrate 202 in FIG. 8 can include multiple layers (e.g., six or more layers), and the passive elements 212 can be implemented on some or all of such multiple layers. In the example context of the filter circuit 100 of FIG. 3A, and by way of examples, the inductance element Lₛₑᵣ can be implemented on layers L2 to L4; the inductance element Lₛ can be implemented on layer L6; the inductance element L_{BW} can be implemented on layer L6; and the capacitance element Cₛ can be implemented on layer L4.

In some embodiments, some or all of the inductance elements Lₛₑᵣ, Lₛ and L_{BW} can be implemented as respective metal traces configured to be substantially uncoupled from each other.

In the example of FIG. 8, the resonators 210a, 210b, 210c, 210d are depicted as separate devices mounted on the packaging substrate 202. However, it will be understood that in some embodiments, the resonators (e.g., S1, P1, S2 and P2 of FIG. 3A) can be implemented a single device, separate devices, or some combination thereof.

In some embodiments, a packaged module having one or more features as described herein can include one or more chips, with at least some of the chip(s) including resonators. For the configuration where a plurality of chips are included, such a module can be implemented as a multi-chip module (MCM) having appropriate electrical connections to provide one or more desired functionalities.

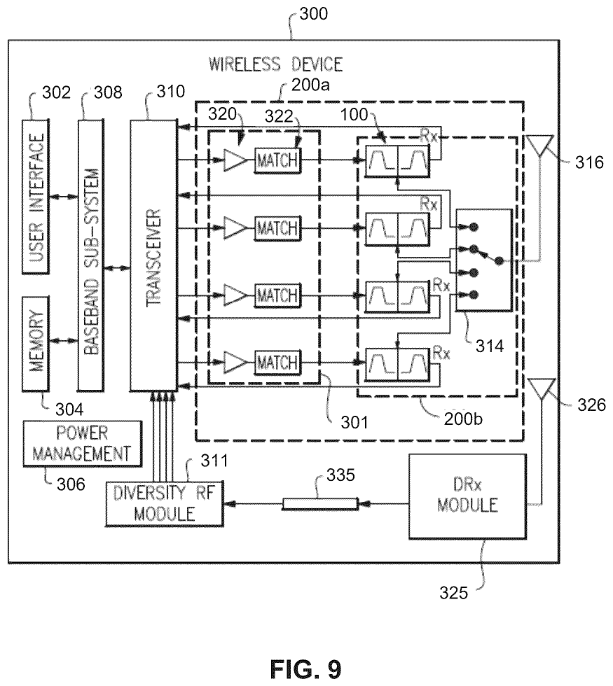

In another example of a product, FIG. 9 shows that in some embodiments, a device and/or a circuit having one or more features described herein can be included in a wireless device. In some embodiments, such a wireless device can include, for example, a cellular phone, a smart-phone, a hand-held wireless device with or without phone functionality, a wireless tablet, etc.

FIG. 9 depicts an example wireless device 300 having one or more advantageous features described herein. In the example of FIG. 9, an RF module having one or more features as described herein can be implemented in one or more places within the wireless device 300. For example, an RF module may be implemented as a front-end module (FEM) indicated as 200a. Such an RF module can be implemented as a multi-chip module as described herein and include one or more filter circuits 100.

In another example, an RF module may be implemented as an antenna switch module (ASM) indicated as 200b. Such an RF module can be implemented as a multi-chip module as described herein and include one or more filter circuits 100.

Referring to FIG. 9, power amplifiers (PAS) 320 can receive their respective RF signals from a transceiver 310 that can be configured and operated to generate RF signals to be amplified and transmitted, and to process received signals. The transceiver 310 is shown to interact with a baseband sub-system 308 that is configured to provide conversion between data and/or voice signals suitable for a user and RF signals suitable for the transceiver 310. The transceiver 310 can also be in communication with a power management component 306 that is configured to manage power for the operation of the wireless device 300.

The baseband sub-system 308 is shown to be connected to a user interface 302 to support various input and output of voice and/or data provided to and received from the user. The baseband sub-system 308 can also be connected to a memory 304 that is configured to store data and/or instructions to support the operation of the wireless device, and/or to provide storage of information for the user.

In the example wireless device 300, outputs of the PAs 320 are shown to be matched (via respective match circuits 322) and routed to their respective duplexers 100, with at least some of such duplexers having a filter circuit as described herein. Such amplified and filtered signals can be routed to a primary antenna 316 through an antenna switch 314 for transmission. In some embodiments, the duplexers 100 can allow transmit and receive operations to be performed simultaneously using a common antenna (e.g., primary antenna 316). In FIG. 9, received signals are shown to be routed to “Rx” paths that can include, for example, a low-noise amplifier (LNA).

In the example of FIG. 9, the wireless device 300 also includes the diversity antenna 326 and a diversity receive module 325 that receives signals from the diversity antenna 326. The diversity receive module 325 can process the received signals and provide the processed signals via a transmission line 335 to a diversity RF module 311 that further processes the signal before feeding the signal to the transceiver 310.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A radio-frequency filter circuit comprising:
a first node and a second node;
a series path implemented between the first and second nodes, the series path including a series resonator;
a shunt path that couples a shunt node along the series path to a ground, the shunt path including a shunt resonator; and
a helper circuit implemented along the shunt path and configured to provide control of a plurality of harmonics associated with a resonance frequency provided by the series and shunt resonators.

2. The radio-frequency filter circuit of claim 1 wherein the radio-frequency filter circuit is configured to provide a band-pass functionality for a frequency band about the resonance frequency.

3. The radio-frequency filter circuit of claim 1 wherein the plurality of harmonics includes a second harmonic and a third harmonic.

4. The radio-frequency filter circuit of claim 1 wherein the helper circuit is implemented between the shunt resonator and the ground.

5. The radio-frequency filter circuit of claim 4 wherein the helper circuit includes a series arrangement of a first inductance Lₛₑᵣ and a parallel combination, such that one end of Lₛₑᵣ is coupled to the shunt resonator and the other end of Lₛₑᵣ is coupled to the parallel combination, the parallel combination including a first path having a second inductance Lₛ in series with a capacitance Cₛ and a second path having a third inductance L_{BW}.

6. The radio-frequency filter circuit of claim 5 wherein Lₛₑᵣ, Lₛ, Cₛ and L_{BW} have values that satisfy a condition
$${ω}^{2} {L}_{s} < \frac{1}{{C}_{s}} < {ω}^{2} ( {L}_{s} + {L}_{BW} ) where ω = 2 π f$$
with f being the resonance frequency.

7. The radio-frequency filter circuit of claim 5 wherein Lₛₑᵣ, Lₛ, Cₛ and L_{BW} have values selected to provide a slightly negative value for an equivalent inductance for the helper circuit.

8. The radio-frequency filter circuit of claim 5 wherein Lₛ and L_{BW} have values selected to have comparable values that are within 50%, 40%, 30%, 20% or 15% of each other.

9. The radio-frequency filter circuit of claim 8 wherein Lₛₑᵣ has a value selected to be greater than each of Lₛ and L_{BW}.

10. The radio-frequency filter circuit of claim 1 further comprising one or more additional sets of a series resonator and a shunt resonator, such that each additional series resonator is implemented along the series path and the respective additional shunt resonator is part of a shunt path that couples a shunt node corresponding to the additional series resonator to the ground.

11. The radio-frequency filter circuit of claim 10 wherein the helper circuit is implemented such that its corresponding shunt node is coupled to one of the first and second nodes or a node between two series resonators.

12. The radio-frequency filter circuit of claim 11 wherein the first node is an input node and the second node is an output node, and the helper circuit is implemented such that its corresponding shunt node is coupled to the input node.

13. A radio-frequency module comprising:
a packaging substrate; and
a filter circuit implemented with respect to the packaging substrate, the filter circuit including a first node and a second node, a series path implemented between the first and second nodes such that the series path includes a series resonator, and a shunt path that couples a shunt node along the series path to a ground such that the shunt path includes a shunt resonator, the filter circuit further including a helper circuit implemented along the shunt path and configured to provide control of a plurality of harmonics associated with a resonance frequency provided by the series and shunt resonators.

14. The radio-frequency module of claim 13 wherein the helper circuit includes a series arrangement of a first inductance Lₛₑᵣ and a parallel combination, such that one end of Lₛₑᵣ is coupled to the shunt resonator and the other end of Lₛₑᵣ is coupled to the parallel combination, the parallel combination including a first path having a second inductance Lₛ in series with a capacitance Cₛ and a second path having a third inductance L_{BW}.

15. The radio-frequency module of claim 14 wherein the packaging substrate includes multiple layers.

16. The radio-frequency module of claim 15 wherein each of Lₛₑᵣ, Lₛ, Cₛ and L_{BW} is implemented as a part of one or more of the multiple layers.

17. The radio-frequency module of claim 13 further comprising one or more chips mounted on the packaging substrate.

18. The radio-frequency module of claim 17 wherein at least some of the one or more chips includes the series resonator and the shunt resonator.

19. The radio-frequency module of claim 13 wherein each of the series and shunt resonators is implemented as an acoustic wave resonator.

20. A wireless device comprising:
an antenna; and
a radio-frequency circuit in communication with the antenna and configured to support either or both of transmit and receive operations of the wireless device, the radio-frequency circuit having a filter circuit that includes a first node and a second node, a series path implemented between the first and second nodes such that the series path includes a series resonator, and a shunt path that couples a shunt node along the series path to a ground such that the shunt path includes a shunt resonator, the filter circuit further including a helper circuit implemented along the shunt path and configured to provide control of a plurality of harmonics associated with a resonance frequency provided by the series and shunt resonators.

21. (canceled)

22. (canceled)
